(19) United States
(12) Patent Application Publication
(10) Pub. No.: US 2024/0274517 A1
(43) Pub. Date: Aug. 15, 2024

(54) SEMICONDUCTOR PACKAGE STRUCTURE, METHOD OF FORMING THE SAME AND SEMICONDUCTOR PACKAGE ASSEMBLY HAVING THE SAME

(71) Applicant: MEDIATEK INC., Hsinchu City (TW)

(72) Inventors: Fa-Chuan CHEN, Hsinchu City (TW); Ta-Jen YU, Hsinchu City (TW); Bo-Jiun YANG, Hsinchu City (TW); Tsung-Yu PAN, Hsinchu City (TW); Tai-Yu CHEN, Hsinchu City (TW); Nai-Wei LIU, Hsinchu City (TW); Shih-Chin LIN, Hsinchu City (TW); Wen-Sung HSU, Hsinchu City (TW)

(21) Appl. No.: 18/418,419

(22) Filed: Jan. 22, 2024

Related U.S. Application Data
(60) Provisional application No. 63/484,760, filed on Feb. 14, 2023.

(51) Int. Cl. H01L 23/498; H01L 21/28; H01L 23/00; H01L 25/065

(52) U.S. Cl. CPC H01L 23/49816; H01L 21/28132; H01L 23/49822; H01L 24/05; H01L 24/13; H01L 25/0652; H01L 2224/05025; H01L 2224/05147; H01L 2224/13025; H01L 2224/13147; H01L 2924/01029; H01L 2924/1436; H01L 2924/15311; H01L 2924/351

(57) ABSTRACT

A semiconductor package structure includes a first component, a bonding structure on the first component, a second component connected to the first component, and a copper connector on the second component. The bonding structure includes a copper base on the first component and copper protruding portions on the copper base. The second component is connected to the first component by bonding the copper protruding portions to the copper connector, and the copper protruding portions are in contact with the copper connector.

### CROSS REFERENCE TO RELATED APPLICATIONS

This Application is based on, and claims priority of U.S. Provisional Application No. 63/484,760 filed on Feb. 14, 2023, the entirety of which is incorporated by reference herein.

### BACKGROUND OF THE INVENTION

### Field of the Invention

The present invention relates to a semiconductor package structure, a method of forming the semiconductor package structure and a semiconductor package assembly having the semiconductor package structure, and in particular to a semiconductor package structure having copper-to-copper bonding sets, a method of forming the same and a semiconductor package assembly having the same.

### Description of the Related Art

Along with the rapid development of semiconductor packaging technologies, different types of semiconductor package structures have been developed for meeting the current trends in semiconductor package fabrication. For example, a semiconductor package structure may include one or more semiconductor dies mounted on a substrate (such as a printed circuit board), or it may include two or more package structures stacked vertically on a substrate (which is known as package-on-package (PoP) technology).

In recent years, as electronic products have become increasingly multifunctional and have been scaled down in size, there is a desire for the manufacturers of semiconductor package structures to incorporate more devices, so that the electronic products that include these devices can be made more compact. This results in many new challenges to the structural and electrical design of semiconductor package structures. For example, a conventional semiconductor package structure can be heated to reflow the solder bumps during the bonding process, and warpage occurs as a result of the mismatch between the thermal coefficient of expansion (CTE) of the top package component and that of the bottom package component. Thus, although existing semiconductor package structures have been adequate for their intended purposes, they have not been entirely satisfactory in all respects.

### BRIEF SUMMARY OF THE INVENTION

Some embodiments of the present disclosure provide semiconductor package structures. An exemplary embodiment of a semiconductor package structure includes a first component, a bonding structure on the first component, a second component connected to the first component, and a copper connector on the second component. The bonding structure includes a copper base on the first component and copper protruding portions on the copper base. The second component is connected to the first component by bonding the copper protruding portions to the copper connector, and the copper protruding portions are in contact with the copper connector.

Some embodiments of the present disclosure provide a method of forming a semiconductor package structure that includes providing a first component. The method includes forming a bonding structure on the first component, wherein the bonding structure includes a copper base on the first component and copper protruding portions on the copper base. The method includes providing a second component with a copper connector formed on it. The method includes connecting the first component to the second component by bonding the copper protruding portions to the copper connector. The copper protruding portions are in contact with the copper connector.

Some embodiments of the present disclosure provide semiconductor package assemblies. An exemplary embodiment of a semiconductor package assembly includes a package substrate, an interposer stacked on the package structure, a first bonding layer between the package structure and the interposer; a device package stacked on the interposer; and a second bonding layer between the device package and the interposer. The device package is electrically connected to the package substrate through the second bonding layer and the first bonding layer. At least one of the first bonding layer and the second bonding layer includes a bonding set. The bonding set includes copper protruding portions between a copper base and a copper connector, and the copper protruding portions are in direct contact with the copper base and the copper connector.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a diagram illustrating an exemplary semiconductor package structure before bonding, in accordance with some embodiments of the present disclosure.

FIGS. 2A, 2B, 2C and 2D are cross-sectional views illustrating intermediate stages of manufacturing an exemplary semiconductor package structure, in accordance with some embodiments of the present disclosure.

FIG. 3A is a diagram illustrating a conventional semiconductor package structure with two solder bumps.

FIG. 3B is a diagram illustrating an exemplary semiconductor package structure with two bonding sets, in accordance with some embodiments of the present disclosure.

FIG. 4 is a diagram illustrating an exemplary semiconductor package structure with two bonding structures on different components before bonding, in accordance with some embodiments of the present disclosure.

FIG. 5A is a diagram illustrating an exemplary semiconductor package structure with bonding structures after bonding, in accordance with some embodiments of the present disclosure. FIG. 5B is an enlarged portion illustrating a circled region C1 of a bonding set shown in FIG. 5A after the first bonding structure is bonded to the second bonding structure.

FIG. 6 is a diagram illustrating an exemplary semiconductor package structure with a bonding structure and a bonding pad before bonding, in accordance with some embodiments of the present disclosure.

FIG. 7A is a diagram illustrating an exemplary semiconductor package structure with bonding structures bonded to bonding pads, in accordance with some embodiments of the present disclosure.

FIG. 7B is an enlarged portion illustrating a circled region C2 of a bonding set shown in FIG. 7A after the bonding structures are bonded to the bonding pads.

FIG. 8 is a diagram illustrating an exemplary semiconductor package structure with bonding structures for heat dissipation, in accordance with some embodiments of the present disclosure.

FIG. 9 is a diagram illustrating an exemplary semiconductor package structure with bonding structures for heat dissipation, in accordance with some embodiments of the present disclosure.

FIG. 10 is a diagram illustrating an exemplary semiconductor package assembly applied with bonding structures, in accordance with some embodiments of the present disclosure.

### DETAILED DESCRIPTION OF THE INVENTION

The inventive concept is described fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the invention.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. Similarly, it should be understood that when an element such as a layer, region or substrate is referred to as being “on” another element, it can be directly on the other element or intervening elements may be present. In contrast, the term “directly” means that there are no intervening elements. It should be understood that the terms “comprises”, “comprising”, “includes” and/or “including”, when used herein, specify the presence of stated features, steps, operations, elements, and/or components, but do not preclude the presence or addition of one or more other features, steps, operations, elements, components, and/or groups thereof.

Furthermore, spatially relative terms, such as “under”, “above”, “lower”, “upper” and the like, may be used herein for ease of description to describe one element or feature's relationship to another element(s) or feature(s) as illustrated in figures. The spatially relative terms are intended to encompass different orientations of the device in use or operation in addition to the orientation depicted in the figures. It should be understood that although the terms first, second, third etc. may be used herein to describe various elements, these elements should not be limited by these terms. These terms are only used to distinguish one element from another element.

Some embodiments of the disclosure are described. It should be noted that additional procedures can be provided before, during, and/or after the stages described in these embodiments. Some of the stages that are described can be replaced or eliminated for different embodiments. Additional features can be added to the semiconductor package.

Some of the features described below can be replaced or eliminated for different embodiments. Although some embodiments are discussed with procedures performed in a particular order, these procedures may be performed in another logical order.

According to some embodiments of the present disclosure, a semiconductor package structure, a method of forming the same and a semiconductor package assembly having the same are described below. In some embodiments, a copper-to-copper bonding in the semiconductor package structure has several advantages such as less degree of warpage of the substrate or wafer, better production yield, reduced pitch between bonding structures, better signal transmission and/or heat dissipation, and competitive cost. Some embodiments are provided below for illustrating the present disclosure.

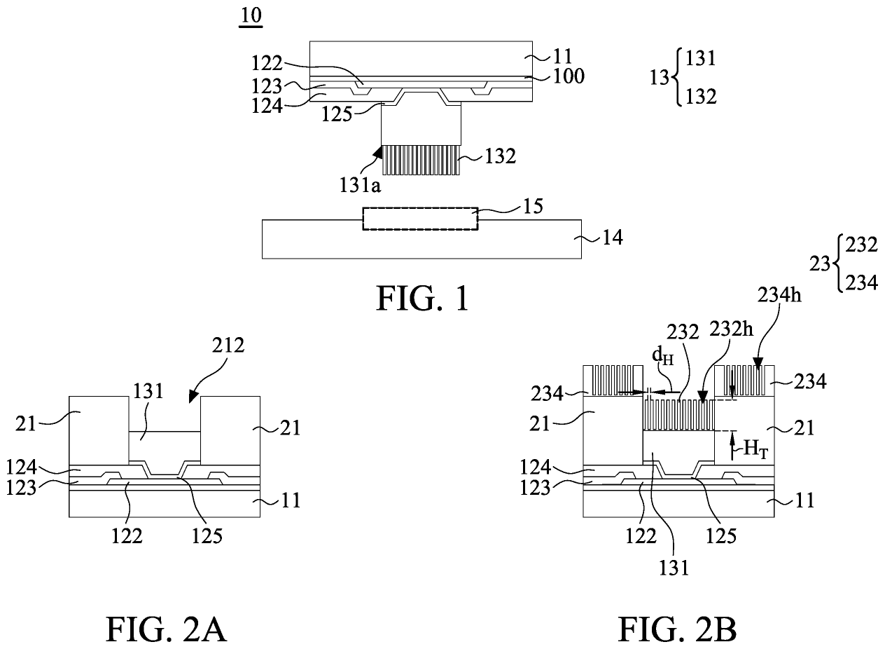

FIG. 1 is a diagram illustrating an exemplary semiconductor package structure before bonding, in accordance with some embodiments of the present disclosure. Referring to FIG. 1, a semiconductor package structure 10 includes a first component 11, a bonding structure 13 on the first component 11, a second component 14, and a copper connector 15 on the second component 14. The second component 14 is electrically connected to the first component 11 by attaching the bonding structure 13 to the copper connector 15. In some embodiments, the bonding structure 13 is formed of copper. The bonding structure 13 is in direct contact with the copper connector 15 when the bonding structure 13 is bonded to the copper connector 15. The first component 11 includes a die, a chip, a system-on-chip (SOC), or any active or passive component.

In some embodiments, the first component 11 may be formed in a substrate 100, and integrated circuits (not shown) may be formed in and/or upon the substrate 100. The substrate 100 may include semiconductor materials, including, but is not limited to, bulk silicon, a semiconductor wafer, a silicon-on-insulator (SOI) substrate, or a silicon germanium substrate. Other semiconductor materials including group III, group IV, and group V elements may also be used. The integrated circuits (not shown) in the substrate 100 refer to electronic circuits having multiple individual circuit elements, such as transistors, diodes, resistors, capacitors, inductors, and active and passive semiconductor devices. The substrate 100 further includes inter-layer dielectric layers (not shown) and a metallization structure (not shown) overlying the integrated circuits. The inter-layer dielectric layers in the metallization structure include low-k dielectric materials, un-doped silicate glass (USG), silicon nitride, silicon oxynitride, or another commonly used material. The dielectric constants (k value) of the low-k dielectric materials may be less than about 3.9 or less than about 2.8. Metal lines in the metallization structure may be formed of copper or copper alloys. For the sake of simplicity, merely a portion of the substrate 100 over the first component 11 is depicted in FIG. 1, and the elements such as the inter-layer dielectric layers and the metallization structure in the substrate 100 are omitted.

In some embodiments, the semiconductor package structure 10 further includes a conductive region 122 that is a top metallization layer formed in a top-level inter-layer dielectric layer. The conductive region 122 is a portion of conductive routs and can be used in a bonding process to connect the integrated circuits in the first component 11 (such as chip) to external features. In one embodiment, the conductive region 122 can be referred to as a pad region. The conductive region 122 may include but is not limited to copper (Cu), aluminum (Al), copper alloy, or another suitable conductive material.

In addition, a first passivation layer 123 is formed on the substrate 100 and patterned to partially cover the conductive region 122. The first passivation layer 123 has an opening to expose a portion of the conductive region 122. The first passivation layer 123 may include but not limited to silicon nitride, silicon oxide, silicon oxynitride, another suitable passivation material, or a combination thereof.

In addition, a second passivation layer 124 is formed above the substrate and covers the first passivation layer 123. As shown in FIG. 1, the second passivation layer 124 covers the top surface and sidewall of the first passivation layer 123, and exposes a portion of the top surface of the conductive region 122. The second passivation layer 124 is conformally formed on the first passivation layer 123 by a deposition process (such as a spin-on coating process), and a subsequent patterning process is performed to expose a portion of the conductive region 122 by forming an opening. The second passivation layer 124 may be formed of a polymer layer, such as an epoxy, polyimide, benzocyclobutene (BCB), polybenzoxazole (PBO), and the like.

In addition, an under bump metallurgy (UBM) layer 125 is formed on the second passivation layer 124 and in direct contact with the exposed portion of the conductive region 122. As depicted in FIG. 1, the UBM layer 125 is conformally formed on the sidewall and the bottom of the opening of the second passivation layer 124. The UBM layer 125 may also extend onto the top surface of the second passivation layer 124. The UBM layer 125 can be a single-layer structure or a multi-layer structure. For example, the UBM layer 125 may include a diffusion barrier layer on the second passivation layer 124 and a seed layer overlying the diffusion barrier layer. The diffusion barrier layer, also referred to as a glue layer, is formed to cover the sidewalls and the bottom of the opening of the second passivation layer 124. The diffusion barrier layer may be formed of tantalum nitride, titanium nitride, tantalum, titanium, or the like, and may be formed by physical vapor deposition (PVD) or sputtering. The seed layer may be a copper seed layer that is formed on the diffusion barrier layer. The seed layer may be formed of copper alloys that include Ag, Cr, Ni, Sn, Au, another suitable metal, and a combination thereof. In one embodiment, the UBM layer 125 is a copper/titanium (Cu/Ti) layer. A single layer of the UBM layer 125 is depicted in the drawings for the sake of simplicity.

In some embodiments, the bonding structure 13 includes a copper base 131 on the first component 11 and copper protruding portions 132 on the copper base 131. As shown in FIG. 1, the copper base 131 is disposed over the first component 11 and in direct contact with the conductive region 122 (such as a pad for a chip). The copper protruding portions 132 are arranged in an array of copper pillars that protrude from the copper base 131 before the first component 11 is bonded to the second component 15. In one embodiment, the copper base 131 has a flat surface 131a, and the copper protruding portions 132 protrude from the flat surface 131a of the copper base 131.

In addition, in some embodiments, the copper protruding portions 132 are copper nano-pillars. The average diameter of the copper protruding portions 132 may be within a range of about 20 nm to about 200 nm, but it is not limited thereto. For example, the diameters of the copper protruding portions 132 are within a range of about 30 nm to about 150 nm, or within a range of about 40 nm to about 100 nm, or within a range of about 50 nm to about 80 nm. In addition, a total area of the copper protruding portions 132 may be about 15% to about 75% or about 20% to about 60% of the area of the copper base 131. Those numerical values are provided for illustrative purpose, and the embodiments of the present disclosure are not limited thereto.

In some embodiments, the second component 14 is a semiconductor wafer, a package substrate, or any component of a semiconductor package structure such as an interposer or a heat spreader. In some other embodiments, the second component 14 is a semiconductor device package; for example, a SOC package, a memory package such as a dynamic random access memory (DRAM) package, or any device package.

In some embodiments, a copper connector 15 is formed on the second component 14. The second component 14 is electrically connected to the first component 11 by bonding the copper protruding portions 132 of the bonding structure 13 to the copper connector 15. Specifically, the copper protruding portions 132 are in direct contact with the copper connector 15. Unlike the traditional method that uses solder bumps for bonding the connectors between two components, a copper-to-copper bonding is applied in the method for attaching the first component 11 to the second component 14, in accordance with some embodiments of the present disclosure.

In addition, the copper connector 15 is a copper portion or a copper structure. For example, the copper connector 15 may be a copper bonding pad or a copper bonding structure that has similar or the same configuration as the bonding structure 13 described above.

One of the methods for forming a semiconductor package structure in some embodiments is provided for exemplification. However, the present disclosure is not limited to the exemplified method. Any suitable method or steps of forming the bonding structure 13 and the copper connector 15 can be applied to complete the manufacture of a semiconductor package structure in some embodiments.

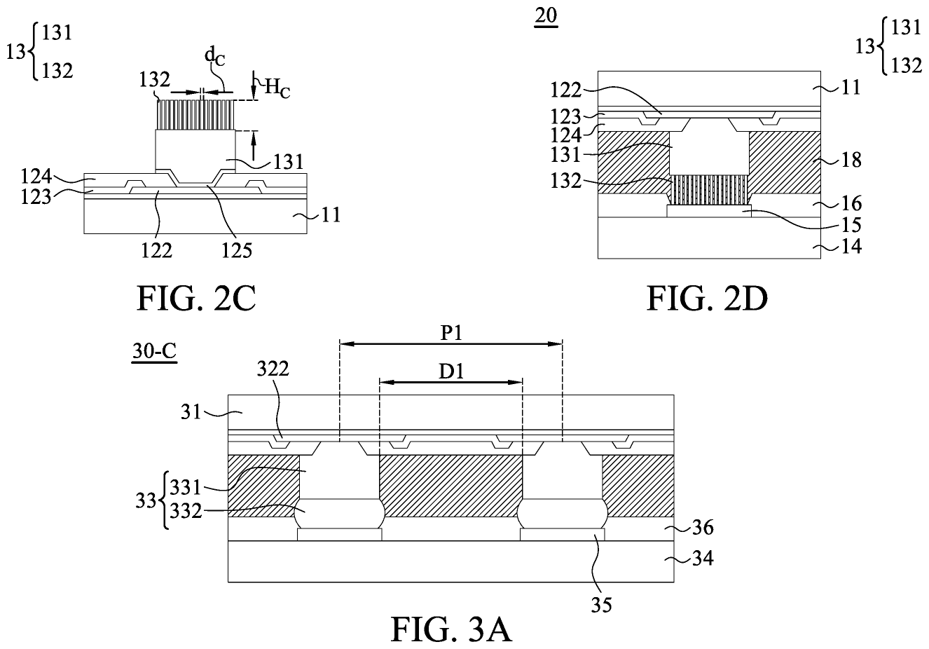

FIGS. 2A, 2B, 2C and 2D are cross-sectional views illustrating intermediate stages of manufacturing an exemplary semiconductor package structure, in accordance with some embodiments of the present disclosure. Referring to FIG. 2A, in some embodiments, a structure that includes the first component 11, the conductive region 122, the first passivation layer 123, the second passivation layer 124 and the UBM layer 125 is provided. Details of those features are similar to the above-mentioned descriptions referring to FIG. 1, and they will not be repeated here. Then, a patterned photoresist layer 21 is formed over the first component 11. The patterned photoresist layer 21 has an opening 212 that exposes the conductive region 122 (e.g. a conductive pad) coupled to the first component 11. A copper portion, as the copper base 131 of the bonding structure 13, is formed by plating copper in the opening 212. The top surface of the copper base 131 may be lower than the top surface of the patterned photoresist layer 21. Alternatively, the top surface of the copper base 131 may be level with the top surface of the patterned photoresist layer 21.

Referring to FIG. 2B, in some embodiments, a template 23 is blanketly coated on the patterned photoresist layer 21 and the copper base 131. The template 23 includes the first portion 232 on the copper base 131 and the second portion 234 on the patterned photoresist layer 21. The first portion 232 has penetrating holes 232h that expose parts of the top surface of the copper base 131. The second portion 234 has penetrating holes 234h that expose parts of the top surface of the patterned photoresist layer 21.

The template 23 may be a porous material layer that includes penetrating holes (e.g., the penetrating holes 232h and 234h) over the copper base 131 and the patterned photoresist layer 21. In some embodiments, the porosity of the template 23 is in a range of about 15% to about 75%, or about 20% to about 60%. In addition, the sizes of the penetrating holes of the template 23 (e.g., the diameters d_{H} of the penetrating holes 232h of the first portion 232) are within a range of about 20 nm to about 200 nm, but they are not limited thereto. For example, the sizes of the penetrating holes of the template 23 are within a range of about 30 nm to about 150 nm, or within a range of about 40 nm to about 100 nm, or within a range of about 50 nm to about 80 nm. In addition, in some embodiments, the porosity of the template 23 is in a range of about 15% to about 75%, or about 20% to about 60%. Those numerical values are provided for illustrative purpose, and the embodiments of the present disclosure are not limited thereto.

Next, in some embodiments, the copper protruding portions 132 are formed on the copper base 131 by plating a copper material in the penetrating holes 232h of the first portion 232 of the template 23. Then, the template 23 and the patterned photoresist layer 21 are removed. Referring to FIG. 2C, in some embodiments, after the template 23 and the patterned photoresist layer 21 are removed, a bonding structure 13 that includes the copper base 131 and the copper protruding portions 132 protruding from the copper base 131 is formed. In addition, the density of the copper protruding portions 132 is determined by the porosity of the template 23, and the dimension of the copper protruding portions 132 is determined by the size of the penetrating holes 232h of the template 23. That is, the diameters d_{H} and the height H_{T} of the penetrating hole 232h of the first portion 232 of the template 23 (FIG. 2B) are equal to the diameter d_{C} and the height H_{C} of the copper protruding portions 132 (FIG. 2C), respectively.

Referring to FIG. 2D, in some embodiments, a second component 14 with a copper connector 15 formed thereon is provided. An insulating layer 16 is formed on the second component 14 and exposes a portion of the top surface of the copper connector 15. Then, the copper protruding portions 132 of the bonding structure 13 are bonded to the copper connector 15. In some embodiments, the bonding structure 13 can be bonded to the copper connector 15 at room temperature. In some embodiments, the bonding structure 13 can be bonded to the copper connector 15 at a temperature ranging from about 25° C. to about 250° C. In addition, the copper connector 15 may be a copper bonding pad or a copper bonding structure that has similar or the same configuration as the bonding structure 13. In FIG. 2D, a copper bonding pad is depicted for the sake of brevity.

After the bonding structure 13 is bonded to the copper connector 15, an underfill layer 18 is formed between the first component 11 and the second component 14. For example, an underfill material is dispensed into the remaining spaces around the bonding structure 13, and fills the gaps between the first component 11 and the second component 14. The underfill material is then cured to form the underfill layer 18 using a curing process.

Compared with the conventional semiconductor package structure having solder bumps, the semiconductor package structure in some embodiments has several advantages, such as less degree of warpage of the substrate or wafer, better production yield, reduced pitch between the bonding structures, better signal transmission and/or heat dissipation, and competitive cost.

For example, a conventional assembly of the semiconductor package structure is heated at a certain high temperature for reflowing the solder bumps, and warpage may occur as a result of thermal coefficient of expansion (CTE) mismatch between the top package component and the bottom package component. The larger the substrate or wafer is, the higher degree of warpage occurs. However, the copper protruding portions 132 of the bonding structure 13 can be bonded to the copper connector 15 at the room temperature, which decreases amounts of thermal accumulation and reduces the degree of warpage. The less degree of warpage increases the production yield of the semiconductor package structure. Moreover, the copper-to-copper bonding that is applied in the method for connecting the first component 11 to the second component 14, in accordance with some embodiments of the present disclosure, prevents the occurrence of melted solder overflow, thereby improving the production yield of the semiconductor package structure.

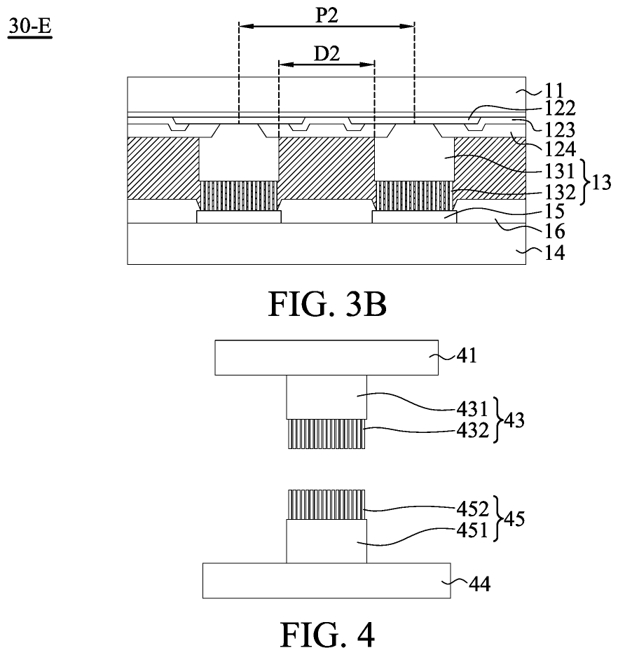

In addition, in some embodiments, the semiconductor package structure has reduced pitch between adjacent bonding structures, which may increase the numbers of the bonding structures and/or reduce dimension of the semiconductor package structure. FIG. 3A is a diagram illustrating a conventional semiconductor package structure 30-C with two solder bumps. FIG. 3B is a diagram illustrating an exemplary semiconductor package structure 30-E with two bonding sets, in accordance with some embodiments of the present disclosure. The features/elements in FIG. 3A and FIG. 3B that are similar or identical to the features/elements in FIG. 1 and FIG. 2D are designated with similar or the same reference numbers, and the details of those similar or the identical features/elements are similar to the related contents in the aforementioned descriptions.

Referring to FIG. 3A, a conventional semiconductor package structure 30-C includes a chip 31, the bonding structures 33 on the pads 322 of the chip 31, a substrate 34 (such as a printed circuit board (PCB)), and the bonding pads 35 on the substrate 34. The chip 31 is electrically connected to the substrate 34 through the bonding sets. Two bonding sets are depicted in FIG. 3A for exemplification. Each bonding set includes the bonding structure 33 and the bonding pad 35. Each of the bonding structures 33 includes a copper portion 331 on the pads 322 and a solder material layer 332 on the copper portion 331. The solder material layer 332 may include dispersed grains of SnAg. In the conventional semiconductor package structure 30-C, the chip 31 is electrically connected to the substrate 34 by bonding the solder material layer 332 to the bonding pad 35, followed by reflowing the solder material layer 332 at a high temperature (such as about 240° C.; the melting point of Sn solder balls is 232° C.) to form the solder joint. FIG. 3A also depicts the pitch P1 of two adjacent bonding sets and the distance D1 between the closest sidewalls of the adjacent bonding sets (such as the sidewalls of the adjacent copper portions 331). Typically, the adjacent bonding sets in the conventional semiconductor package structure 30-C are separated from each other by a sufficient distance (such as the distance D1 in FIG. 3A) for the melted solder material flowing outwardly.

Referring to FIG. 3B, a semiconductor package structure 30-E includes a first component 11, a bonding structure 13 on the first component 11, a second component 14, and a copper connector 15 on the second component 14. Two bonding sets are depicted in FIG. 3B for exemplification. Each bonding set includes the bonding structure 13 and the copper connector 15. Each of the bonding structures 13 includes a copper base 131 on the conductive region 122 (such as a pad for a chip) of the first component 11 and the copper protruding portions 132 on the copper base 131. Details of the configurations and the materials of the features/elements of the semiconductor package structure 30-E in FIG. 3B are similar to the above-mentioned descriptions referring to FIG. 1 and FIG. 2D, and they will not be repeated here. According to the method for electrically connecting the first component 11 to the second component 14 by copper-to-copper bonding between the copper protruding portions 132 and the copper connector 15, in accordance with some embodiments of the present disclosure, there is no flowing solder issue of concern.

FIG. 3B also depicts the pitch P2 of two adjacent bonding sets and the distance D2 between the closest sidewalls of the adjacent bonding sets (such as the sidewalls of the adjacent copper bases 131). Without considering occurrence of flowing solder, the adjacent bonding sets in the semiconductor package structure 30-E can be arranged more closer than the adjacent bonding sets in the conventional semiconductor package structure 30-C. That is, the distance D2 in FIG. 3B is less than the distance D1 in FIG. 3A, and the pitch P2 in FIG. 3B is less than the pitch P1 in FIG. 3A (i.e., D2<D1, and P2<P1). Thus, compared with the configuration of bonding sets in the conventional semiconductor package structure 30-C, more bonding sets can be arranged in the semiconductor package structure of the embodiment for electrically connecting the first component 11 (e.g., a chip) and the second component 14 (e.g., a substrate), thereby improving the performance efficiency of the semiconductor package structure.

In addition, the semiconductor package structure of the embodiments can be used in various types of the semiconductor package structures in the applications. Some applications with different configurations of the semiconductor package structures are provided below for exemplification. However, the present disclosure is not limited thereto.

FIG. 4 is a diagram illustrating an exemplary semiconductor package structure with two bonding structures on different components before bonding, in accordance with some embodiments of the present disclosure. The features/elements in FIG. 4 that are similar or identical to the features/elements in FIG. 1 and FIG. 2D are designated with similar or the same reference numbers, and the details of those similar or the identical features/elements are similar to the related contents in the aforementioned descriptions.

Referring to FIG. 4, in this exemplary embodiment, a copper connector on the second component 44 is another bonding structure that has the same configuration as the bonding structure on the first component 41. In addition, in this exemplary embodiment, the first component 41 is a chip, and the second component 44 is a semiconductor wafer for illustrative purposes. The embodiments of the present disclosure are not limited thereto.

Specifically, in this exemplary embodiment, the bonding structure on the first component 41 can be referred to as a first bonding structure 43. The copper connector on the second component 44 can be referred to as a second bonding structure 45, which has the same configuration as the first bonding structure 43. As shown in FIG. 4, the first bonding structure 43 includes the first copper base 431 on the first component 41 (e.g. a chip) and the first copper protruding portions 432 on the first copper base 431. The second bonding structure 45 includes the second copper base 451 on the second component 45 (e.g. a wafer) and the second copper protruding portions 452 on the second copper base 451. In addition, FIG. 4 shows the first bonding structure and the second bonding structure before bonding to each other. That is, the first copper protruding portions 432 are arranged in an array of copper pillars that protrude from the first copper base 431, and the second copper protruding portions 452 are arranged in an array of copper pillars that protrude from the second copper base 451 before the first copper protruding portions 432 are bonded to the second copper protruding portions 452.

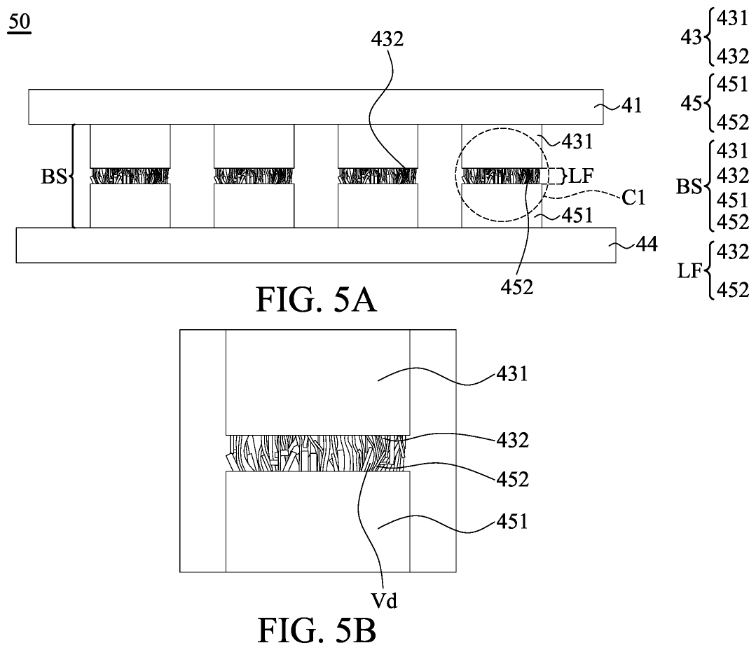

FIG. 5A is a diagram illustrating an exemplary semiconductor package structure with bonding structures after bonding, in accordance with some embodiments of the present disclosure. FIG. 5B is an enlarged portion illustrating a circled region C1 of a bonding set shown in FIG. 5A after the first bonding structure is bonded to the second bonding structure. The features/elements in FIG. 5A and FIG. 5B that are similar or identical to the features/elements in FIG. 4 are designated with similar or the same reference numbers, and the details of those similar or the identical features/elements are similar to the related contents in the aforementioned descriptions. In addition, details of the configurations and the materials of the features/elements of the semiconductor package structure 50 in FIG. 5A are similar to the above-mentioned descriptions referring to FIG. 4, and they will not be repeated here.

In addition, four bonding sets BS are depicted in FIG. 5A for illustrating this exemplary embodiment. Each of the bonding sets BS includes the first bonding structure 43 and the second bonding structure 45. However, the present disclosure is not limited thereto. The number of the bonding sets BS between the first component 41 (e.g. a chip) and the second component 45 (e.g. a wafer) can be varied and determined according to the requirements of the electrical connection between the first component 41 and the second component 45.

Referring to FIG. 5A and FIG. 5B, when the first bonding structure 43 is bonded to the second bonding structure 45, the first copper protruding portions 432 are staggered with respect to the second copper protruding portions 452, and the first copper protruding portions 432 are in direct contact with the second copper protruding portions 452. After the first bonding structure 43 is bonded to the second bonding structure 45 through the copper-to-copper bonding, the first component 41 is electrically connected to the second component 44.

In some embodiments, after the first bonding structure 43 is bonded to the second bonding structure 45, the first copper protruding portions 432 and the second copper protruding portions 452 form a fused layer LF having copper pillars, which can also be referred to as a copper fused layer LF. The diameters of the first copper protruding portions 432 and the second copper protruding portions 452 may be in nanoscopic scale. Thus, the first copper protruding portions 432 and the second copper protruding portions 452 may form a fused layer LF having copper nano-pillars.

In addition, in some embodiments, the copper fused layer LF has voids Vd that are randomly distributed in the copper fused layer LF. The voids Vd are vacancies or slits, which are formed between the first copper protruding portions 432 and the second copper protruding portions 452. As shown in FIG. 5B, the voids Vd have irregular shapes and irregular sizes. Some areas of the copper fused layer LF may have bigger voids Vd, while some other areas of the copper fused layer LF may have smaller voids Vd or no voids Vd. It should be noted that dimensions, shapes and positions of the voids Vd in the copper fused layer LF in FIG. 5B are provided for illustrative purposes, and the embodiments of the present invention are not limited thereto.

In some embodiments, the first bonding structure 43 can be bonded to the second bonding structure 45 at room temperature. The first copper protruding portions 432 and the second copper protruding portions 452 are staggered and in direct contact with each other at room temperature. In addition, after the first bonding structure 43 is bonded to the second bonding structure 45, one or more thermal treatments may be performed on the first bonding structure 43 and the second bonding structure 45. The aforementioned thermal treatments may be provided by one or more thermal processes in the subsequent manufacture of the semiconductor package structure. In an alternative embodiment, an extra annealing treatment is performed for heating the first bonding structure 43 and the second bonding structure 45 after the first bonding structure 43 is bonded to the second bonding structure 45.

In addition, in some other embodiments, the first bonding structure 43 can be bonded to the second bonding structure 45 at a temperature ranging from about 25° C. to about 250° C. One or more thermal processes in the subsequent manufacture or an extra annealing treatment may be provided for improving the connection between the first copper protruding portions 432 and the second copper protruding portions 452.

In addition, the first bonding structure 43 may be bonded to the second bonding structure 45 in a short time. In some embodiments, the first bonding structure 43 can be bonded to the second bonding structure 45 for about 30 second or less than 30 second; for example, for about 1 second or less than 1 second. In some embodiments, the bonding time is in a range of 0.5 second to 1 minute. Those numerical values are provided for illustrative purposes, and the embodiments of the present disclosure are not limited thereto.

In addition, the first bonding structure 43 may be bonded to the second bonding structure 45 at a forcing pressure, such as a pressure ranging from about 1 MPa to about 15 MPa, or another pressure in a suitable range. In some other embodiments, the first bonding structure 43 can be bonded to the second bonding structure 45 in the absence of a forcing pressure.

According to the embodiments, after the first bonding structure 43 and the second bonding structure 45 are subjected to one or more thermal processes in the subsequent manufacture or an extra annealing treatment, the first copper protruding portions 432 and the second copper protruding portions 452 would be partially melted, which enhances copper diffusion between the first copper protruding portions 432 and the second copper protruding portions 452. In addition, in some embodiments, after one or more thermal processes in the subsequent manufacture or an extra annealing treatment is performed on the first bonding structure 43 and the second bonding structure 45, the sizes of the voids Vd in the copper fused layer LF would be reduced, and/or the number of the voids Vd in the copper fused layer LF would be decreased.

Although the semiconductor package structures in FIG. 4 and FIG. 5A include the first bonding structure 43 with the first copper protruding portions 432 and the second bonding structure 45 with the second copper protruding portions 452, the present disclosure is not limited thereto. The copper-to-copper bonding can be achieved by the bonding structure with copper protruding portions being in direct contact with a copper bonding pad.

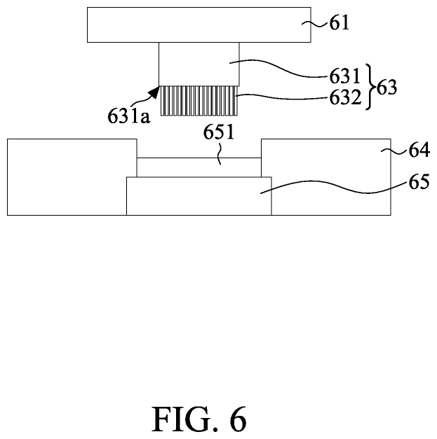

FIG. 6 is a diagram illustrating an exemplary semiconductor package structure with a bonding structure and a bonding pad before bonding, in accordance with some embodiments of the present disclosure. The features/elements in FIG. 6 that are similar or identical to the features/elements in FIG. 1 are designated with similar or the same reference numbers, and the details of those similar or the identical features/elements are similar to the related contents in the aforementioned descriptions.

Referring to FIG. 6, in this exemplary embodiment, a semiconductor package structure includes a first component 61, a bonding structure 63 on the first component 61, a second component 64, and a copper connector 65 on the second component 64. In this exemplary embodiment, the first component 61 is a chip, and the second component 64 is a package substrate for illustrative purposes; however, the embodiments of the present disclosure are not limited thereto.

In this exemplary embodiment, the bonding structure 63 includes the copper base 631 on the first component 61 (e.g. a chip) and the copper protruding portions 632 on the copper base 631. In addition, FIG. 6 shows that the copper protruding portions 632 are arranged in an array of copper pillars that protrude from the surface 631a of the first copper base 631 before the bonding structure 63 is bonded to the copper connector 65. In addition, in some embodiments, a solder-free film 651, such as a copper-containing film or a palladium-containing film (such as a film formed by an electroless nickel/electroless palladium/immersion gold-plating (ENEPIG) method), may be optionally formed on the copper connector 65 for improving the adhesion between the copper protruding portions 632 and the copper connector 65.

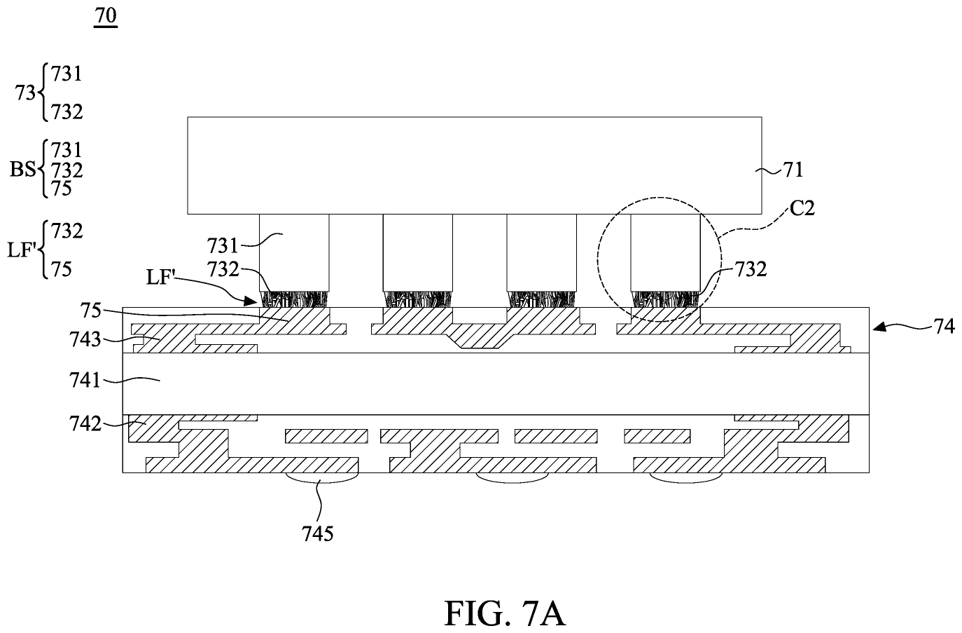

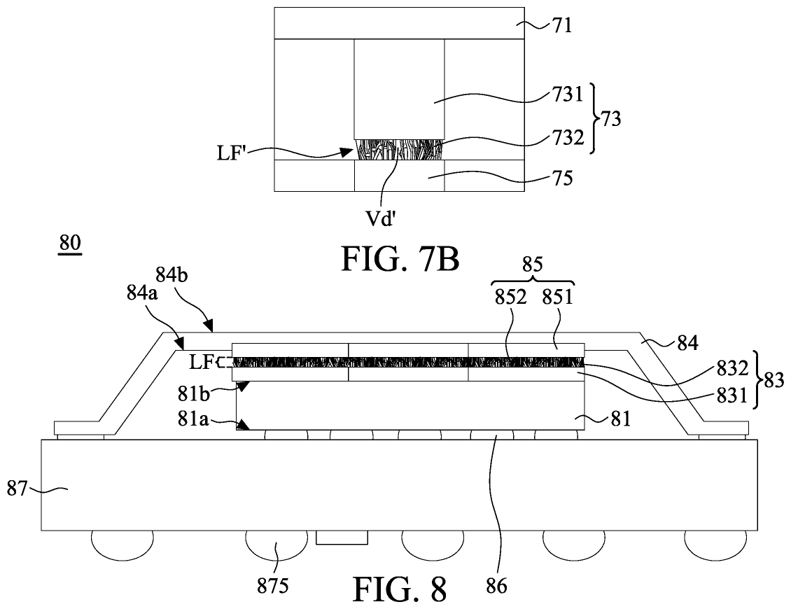

FIG. 7A is a diagram illustrating an exemplary semiconductor package structure with bonding structures bonded to bonding pads, in accordance with some embodiments of the present disclosure. FIG. 7B is an enlarged portion illustrating a circled region C2 of a bonding set shown in FIG. 7A after the bonding structures are bonded to the bonding pads. The features/elements in FIGS. 7 and 7A that are similar or identical to the features/elements in FIG. 6 are designated with similar or the same reference numbers, and the details of those similar or the identical features/elements are similar to the related contents in the aforementioned descriptions. In addition, details of the configurations and the materials of the features/elements of the semiconductor package structure 70 in FIG. 7A that are similar to the above-mentioned descriptions referring to FIG. 4 will not be repeated here.

In addition, four bonding sets BS are depicted in FIG. 7A for illustrating this exemplary embodiment. Each of the bonding sets BS includes the bonding structure 73 and the copper connector 75 (e.g. the bonding pad) on the second component 74 (e.g., a package substrate). However, the present disclosure is not limited thereto. It should be noted that the number of the bonding sets BS between the first component 71 (e.g. a chip) and the second component 74 can be varied and determined according to the requirements of the electrical connection between the first component 71 and the second component 75.

Referring to FIG. 7A, in some embodiments, a package substrate is provided as the second component 74. The package substrate may include a core 741, the inter-metal dielectric (IMD) layers 742 and interconnect traces 743 disposed in the inter-metal dielectric layers 742. The interconnect traces 743 on opposite sides of the core 741 may be electrically connected to each other by through-vias (not shown). In addition, the copper connectors 75 (e.g. the bonding pads) may be formed on the top of the package substrate. Several conductive structure (such as solder balls) 745 can be formed on the bottom of the package substrate. The package substrate can be coupled to an external electronic device, such as a printed circuit board (PCB), through the conductive structure 745.

Referring to FIG. 7A and FIG. 7B, when the bonding structure 73 is bonded to the second component 75, the copper protruding portions 732 on the copper base 731 are in direct contact with the copper connector 75 (e.g. the bonding pad). That is, the first component 71 is electrically connected to the second component 74 by copper-to-copper bonding between the bonding structures 73 and the respective copper connectors 75.

In addition, in some embodiments, after the bonding structures 73 are bonded to the respective copper connectors 75, an underfill layer (not shown) is formed between the first component 71 and the second component 74. In some embodiments, an underfill material may be dispensed into the remaining spaces around the bonding structures 73 and fills the gaps between the first component 71 and the second component 74. The underfill material is then cured to form the underfill layer using a curing process. The underfill layer may be formed by a capillary flow process or another suitable method.

In addition, in some embodiments, after the bonding structure 73 is bonded to the copper connector 75 (e.g. the bonding pad), the copper protruding portions 732 and the copper connector 75 form a fused layer LF′ having copper pillars, which can also be referred to as a copper fused layer LF′. The diameters of the copper protruding portion 732 may be in nanoscopic scale. Thus, the copper protruding portions 732 and the copper connector 75 may form a fused layer LF′ having copper nano-pillars.

In addition, in this exemplary embodiment, the copper fused layer LF′ has voids Vd′ that are randomly distributed in the copper fused layer LF′. The voids Vd′ are vacancies or slits in the copper fused layer LF′, which are formed between the copper protruding portions 732 and the copper connector 75 (e.g. the bonding pad) that is butted against the copper protruding portions 732. As shown in FIG. 7B, the voids Vd′ have irregular shapes and irregular sizes. Some areas of the copper fused layer LF′ may have bigger voids Vd′, while some other areas of the copper fused layer LF′ may have smaller voids Vd′ or almost void-free. It should be noted that dimensions, shapes and positions of the voids Vd′ in the copper fused layer LF′ in FIG. 7B are provided for illustrative purposes, and the embodiments of the present invention are not limited thereto.

In addition, in some embodiments, the bonding structure 73 can be bonded to the copper connector 75 (e.g. the bonding pad) at room temperature. In some embodiments, after the copper protruding portions 732 of the bonding structure 73 are in contact with the copper connector 75, one or more thermal treatments are performed on the bonding structure 73 and the copper connector 75. The aforementioned thermal treatments may be provided by one or more thermal processes in the subsequent manufacture of the semiconductor package structure. In an alternative embodiment, an extra annealing treatment is performed for heating the bonding structure 73 and the copper connector 75 after the bonding structure 73 is bonded to the copper connector 75.

In addition, in some other embodiments, the bonding structure 73 can be bonded to the copper connector 75 (e.g. the bonding pad) at a temperature ranging from about 25° C. to about 250° C. One or more thermal processes in the subsequent manufacture or an extra annealing treatment may be provided for improving the connection between the copper protruding portions 732 and the copper connector 75.

According to the embodiments, after the bonding structure 73 and the copper connector 75 are subjected to one or more thermal processes in the subsequent manufacture or an extra annealing treatment, the copper protruding portions 732 and the copper connector 75 would be partially melted, which enhances copper diffusion between the copper protruding portions 732 and the copper connector 75. In addition, after one or more thermal processes in the subsequent manufacture or an extra annealing treatment is performed on the bonding structure 73 and the copper connector 75, the sizes of the voids Vd′ in the copper fused layer LF′ would be reduced, and/or the number of the voids Vd′ in the copper fused layer LF′ would be decreased.

Although the copper-to-copper bonding of the exemplary semiconductor package structures in FIG. 5A and FIG. 7A are provided for achieving the electrical connection between an upper component (such as the first component 41/61/71) and a lower component (such as the second component 44/64/74) of the semiconductor package structure, the present disclosure is not limited thereto. The copper-to-copper bonding can also be constructed for improving the heat dissipation of the semiconductor package structure.

FIG. 8 is a diagram illustrating an exemplary semiconductor package structure with bonding structures for heat dissipation, in accordance with some embodiments of the present disclosure. The features/elements in FIG. 8 that are similar or identical to the features/elements in FIG. 4, and FIG. 5A are designated with similar or the same reference numbers, and the details of those similar or the identical features/elements are similar to the related contents in the aforementioned descriptions.

Referring to FIG. 8, in this exemplary embodiment, a semiconductor package structure 80 includes a first component 81, a first bonding structure 83 on the first component 81, a second component 84, and a second bonding structure 85 on the second component 84. In this exemplary embodiment, the first component 81 is (but not limited to) a die, and the second component 84 is (but not limited to) a heat spreader for illustrative purposes.

In this exemplary embodiment, the first bonding structure 83 includes the first copper base 831 on the first component 81 (e.g. a die) and the first copper protruding portions 832 on the first copper base 831. The second bonding structure 85 includes the second copper base 851 on the second component 84 (e.g. a heat spreader) and the second copper protruding portions 852 on the second copper base 851.

Specifically, the first component 81 (e.g. a die) has a frontside 81a and a backside 81b. The first bonding structure 83 is formed on the backside 81b of the first component 81. For example, the first copper base 831 is in contact with the backside 81b of the die. In addition, in one embodiment, the first component 81 is mounted on a substrate 87 with conductive balls 875. The substrate 87 may be a flip chip ball grid array (FCBGA) substrate or another suitable substrate. In this exemplary embodiment, the first component 81 is electrically connected to the substrate 87 through several conductive connectors 86 in contact with the frontside 81a of the first component 81 and the substrate 87.

In addition, in this exemplary embodiment, the second component 84 (e.g. a heat spreader) has the first surface 84a and the second surface 84b. The first surface 84a of the second component 84 faces the backside 81b of the first component 81. The second bonding structure 84 is formed on the first surface 84a of the second component 84. When the second component 84 is mounted on the substrate 87, the first copper protruding portions 832 are staggered with respect to the second copper protruding portions 852, and the first copper protruding portions 832 are in direct contact with the second copper protruding portions 852. After the first bonding structure 83 on the die is bonded to the second bonding structure 85 on the heat spreader, the copper-to-copper bonding, implemented by a combination of the first bonding structure 83 and the second bonding structure 85, improves dissipation of the heat that is generated by the die.

In addition, in some embodiments, after the first bonding structure 83 is bonded to the second bonding structure 85, the first copper protruding portions 832 and the second copper protruding portions 852 may form a fused layer LF having copper pillars, which can also be referred to as a copper fused layer LF. In some embodiments, the first copper protruding portions 832 and the second copper protruding portions 852 may form a fused layer LF having copper nano-pillars, if the dimensions of the first copper protruding portions 832 and the second copper protruding portions 852 are in nanoscopic scale.

In some embodiments, the first bonding structure 83 can be bonded to the second bonding structure 85 at room temperature. In addition, after the first bonding structure 83 is bonded to the second bonding structure 85, one or more thermal processes in the subsequent manufacture or an extra annealing treatment may be provided for enhancing copper diffusion between the first copper protruding portions 832 and the second copper protruding portions 852, thereby improving the heat dissipation paths between the first copper protruding portions 832 and the second copper protruding portions 852.

Although, the first bonding structure 83 and the second bonding structure 85 are depicted as continuous layers in FIG. 8, the present disclosure is not limited thereto. In some embodiments, the first bonding structure 83 and the second bonding structure 85 can be formed as several discrete blocks between the first component 81 and the second component 84 to dissipate the heat generated by the first component 81. In addition, in some other embodiments, it should be noted that the second bonding structure 85 can be replaced by a copper connector 65 such as a bonding pad shown in FIG. 7A. The present disclosure is not limited to the configuration of the exemplary embodiment in FIG. 8.

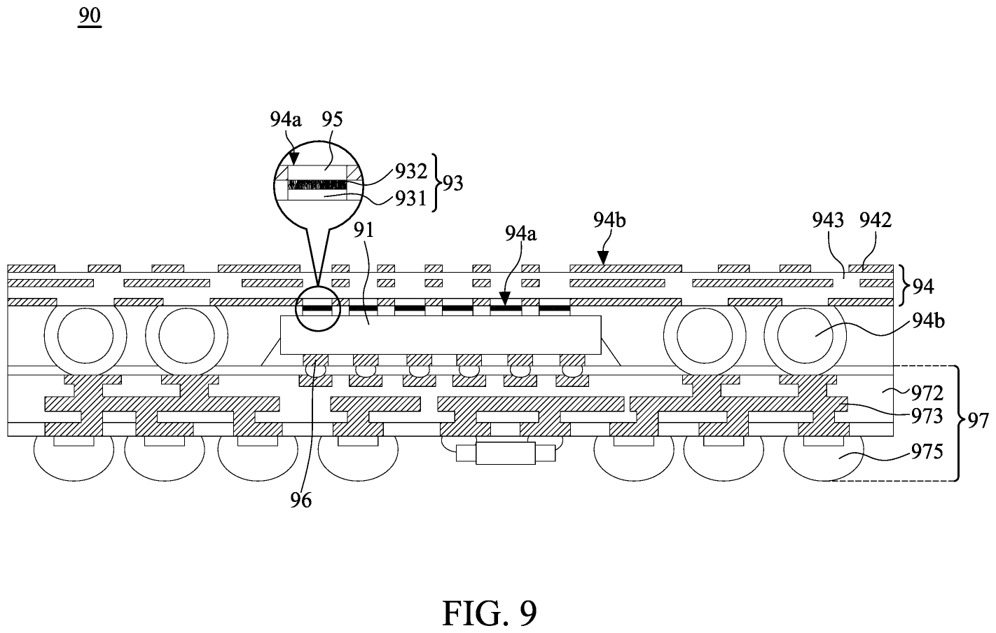

FIG. 9 is a diagram illustrating an exemplary semiconductor package structure with bonding structures for heat dissipation, in accordance with some embodiments of the present disclosure. The features/elements in FIG. 9 that are similar or identical to the features/elements in FIG. 7A are designated with similar or the same reference numbers, and the details of those similar or the identical features/elements are similar to the related contents in the aforementioned descriptions.

Referring to FIG. 9, in this exemplary embodiment, a semiconductor package structure 90 includes a first component 91, a bonding structure 93 on the first component 91, a second component 94, and a copper connector 95 on the second component 94. In this exemplary embodiment, the first component 91 may be a die, and the second component 94 may be an interposer substrate, but this is for illustrative purposes and they are not limited thereto.

In this exemplary embodiment, each of the bonding structures 93 includes the copper base 931 on the first component 91 (e.g. a die) and the copper protruding portions 932 on the copper base 931. In addition, as shown in FIG. 9, the bonding structures 93 are formed on the backside 91b of the die (i.e., the first component 91). For example, the copper bases 931 of the bonding structures 93 are in contact with the backside 91b of the die.

In addition, as shown in FIG. 9, the copper connectors 95 may be a copper bonding pad and formed on an interposer substrate (i.e., the second component 94). The interposer substrate may include the IMD layers 942 and interconnect traces 943 disposed in the inter-metal dielectric layers 942. In this exemplary embodiment, the interposer substrate may have the first surface 94a and the second surface 94b. The first surface 94a of the interposer substrate faces the backside 91b of the die. When the interposer substrate (i.e., the second component 94) is mounted on the die (i.e., the first component 91), the copper bonding pads (i.e., the copper connectors 95) are in direct contact with the copper protruding portions 932 of the respective bonding structures 93. According to the embodiment, the copper-to-copper bonding, implemented by a combination of the bonding structures 93 and the respective copper connectors 95, improves dissipation of the heat that is generated by the die (i.e., the first component 91). In some other embodiments, the combination of the bonding structures 93 and the respective copper connectors 95 may also improve electrical connection between the interposer substrate (i.e., the second component 94) and the die (i.e., the first component 91), depending on the actual design of the application.

In addition, in one embodiment, the die (i.e., the first component 91) is mounted on a substrate 97 with conductive balls 975. The substrate 97 may include the IMD layers 972 and interconnect traces 973 disposed in the IMD layers 972. In this exemplary embodiment, the die (i.e., the first component 91) is electrically connected to the substrate 97 through several conductive connectors 96 at the frontside 91a of the die and the substrate 97. The substrate 97 can be coupled to an external electronic device, such as a printed circuit board (PCB), through the conductive structure 945. The interconnect traces 943 of the interposer substrate (i.e., the second component 94) are connected to the interconnect traces 973 of the substrate 97 through the conductive structures 946 (may be formed of Cu, Al or W). In addition, it should be noted that the copper connectors 95 can be replaced by the second bonding structure 85 shown in FIG. 8. The present disclosure is not limited to the configuration of the exemplary embodiment in FIG. 9.

The copper-to-copper bonding that is implemented by a combination of the bonding structures and the respective copper connectors, in accordance with some embodiments of the present disclosure, can be applied in various types of semiconductor package assemblies. One of the semiconductor package assemblies is provided for exemplification. However, the present disclosure is not limited thereto.

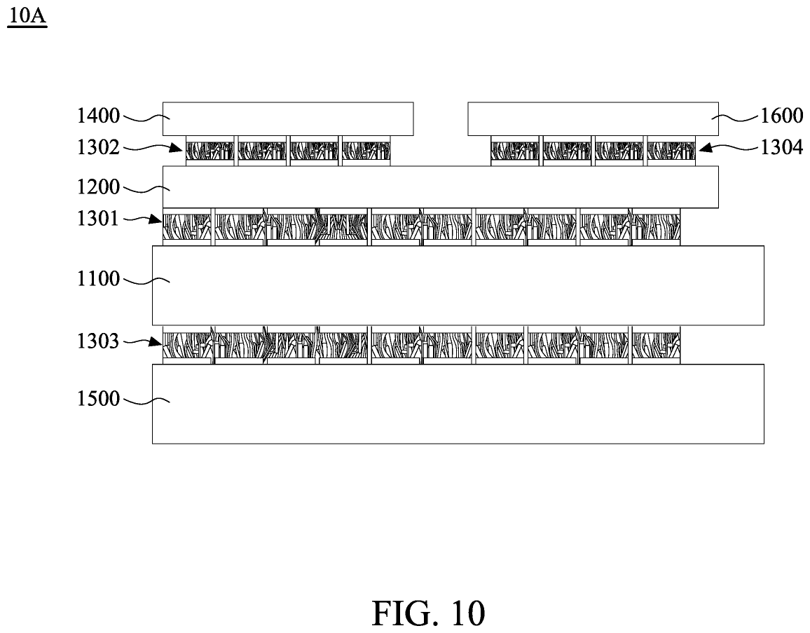

FIG. 10 is a diagram illustrating an exemplary semiconductor package assembly applied with bonding structures, in accordance with some embodiments of the present disclosure. Referring to FIG. 10, in some embodiments, a semiconductor package assembly 10A includes a package substrate 1100, an interposer 1200 stacked on the package structure 1100, a first bonding layer 1301 formed between the package structure 1100 and the interposer 1200, at least a device package 1400 stacked on the interposer 1200, and a second bonding layer 1302 formed between the device package 1400 and the interposer 1200. The device package 1400 is electrically connected to the package substrate 1100 through the second bonding layer 1302 and the first bonding layer 1301.

In some embodiments, one or both of the first bonding layer 1301 and the second bonding layer 1302 include bonding sets for electrical connection and/or heat dissipation. A bonding set may include a copper base, a copper connector, and copper protruding portions between the copper base and the copper connector, as described in the foregoing embodiments. In some embodiments, the copper protruding portions are in direct contact with the copper base and the copper connector.

Details of the configurations and materials of the copper base and the copper protruding portions of the bonding set in FIG. 10 can be referred to the above-mentioned descriptions of the related contents of the copper base 131/431/731/831 and the copper protruding portions 132/432/732/832 in FIG. 3B, FIG. 5A, FIG. 7A and FIG. 8, and are not repeated herein for the sake of simplicity and clarity.

In addition, details of the configuration and material of the copper connector of the bonding set in FIG. 10 can be referred to the above-mentioned descriptions of the related contents of the copper connector 15/75/95 in FIG. 3B, FIG. 7A and FIG. 9, or the related contents of the second bonding structure 45/85 in FIG. 4 and FIG. 8. Those are not repeated herein for the sake of simplicity and clarity.

In some embodiments, the copper base and the copper connector are disposed on different components. In one example, if the first bonding layer 1301 includes the bonding set, the copper base and the copper connector may be disposed on the package structure 1100 and the interposer 1200, respectively. The copper protruding portions are positioned between the copper base and the copper connector after the interposer 1200 is boded to the package structure 1100. In addition, after the interposer 1200 is boded to the package structure 1100, the copper protruding portions and the copper connector may form a copper fused layer that includes fused nano-copper pillars and voids randomly distributed between the fused nano-copper pillars, as described above.

In one example, if the second bonding layer 1302 includes the bonding set, the copper base and the copper connector may be disposed on the device package 1400 and the interposer 1200, respectively. The copper protruding portions are positioned between the copper base and the copper connector after the device package 1400 is boded to the interposer 1200. In addition, after the device package 1400 is boded to the interposer 1200, the copper protruding portions and the copper connector may form a copper fused layer that includes fused nano-copper pillars and voids randomly distributed, as described above.

In addition, in some embodiments, the semiconductor package assembly 10A further includes a printed circuit board (PCB) 1500 under the package substrate 1100, and coupled to the package substrate 1100 by the third bonding layer 1303. The third bonding layer 1303 may include one or more bonding sets each having the identical configuration as the bonding set of the first bonding layer 1301 and/or the second bonding layer 1302.

In addition, in some embodiments, the semiconductor package assembly 10A may include several device packages on the interposer 1200. For example, the semiconductor package assembly 10A further includes another device package 1600 that is mounted on the interposer 1200. The device package 1600 is coupled to the interposer 1200 by the fourth bonding layer 1304. The fourth bonding layer 1304 may include one or more bonding sets each having the identical configuration as the bonding set of the first bonding layer 1301 and/or the second bonding layer 1302. In one example, the device package 1400 is, but not limited to, a system-on-chip (SOC) package, and the device package 1600 is, but not limited to, a memory package (e.g., DRAM package). However, the present disclosure has no limitation to the types and number of the device packages 1400 and 1600. The components of the semiconductor package assembly 10A can be selected and varied depending on the practical requirements of the application.

According to some embodiments described above, the semiconductor package structure has several advantages, such as less degree of warpage of the substrate or wafer, better production yield, reduced pitch between the bonding structures, better signal transmission and/or heat dissipation, and competitive cost. For example, a copper-to-copper bonding, such as copper protruding portions of a bonding structure bonded to the copper connector (e.g., copper bonding pads or copper protruding portions of another bonding structure) can be achieved at the room temperature, which decreases amounts of thermal accumulation and reduces the degree of warpage of the substrate or wafer. The less degree of warpage increases the production yield of the semiconductor package structure. Moreover, the copper-to-copper bonding that is applied in the method for connecting two components (e.g., connecting the first component 11 and the second component 14), in accordance with some embodiments of the present disclosure, prevents the occurrence of melted solder overflow, thereby improving the production yield of the semiconductor package structure. In addition, in some embodiments, the semiconductor package structure has reduced pitch between adjacent bonding structures, which may increase the numbers of the bonding structures and/or reduce the dimension of the semiconductor package structure. In addition, the copper-to-copper bonding of the embodiments provides better signal transmission and/or heat dissipation paths for the semiconductor package structure or the semiconductor package assembly, which improves the electrical performance and/or increases efficiency of the heat dissipation efficiency. In addition, compared with the conventional semiconductor package structure having solder bumps (which requires a reflow apparatus to reflow the solder bumps), the copper-to-copper bonding of the embodiments can be completed in a short time and there is no need to perform a reflow step for the copper-to-copper bonding, which save manufacture time and production cost.

It should be noted that the details of the structures of the embodiments are provided for exemplification, and the described details of the embodiments are not intended to limit the present disclosure. It should be noted that not all embodiments of the invention are shown. Modifications and variations can be made without departing from the spirit of the disclosure to meet the requirements of the practical applications. Thus, there may be other embodiments of the present disclosure which are not specifically illustrated. Furthermore, the accompanying drawings are simplified for clear illustrations of the embodiment. Sizes and proportions in the drawings may not be directly proportional to actual products. Thus, the specification and the drawings are to be regard as an illustrative sense rather than a restrictive sense.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a first component;
a bonding structure on the first component, the bonding structure comprising:
a copper base disposed on the first component; and
copper protruding portions disposed on the copper base;
a second component connected to the first component; and
a copper connector on the second component,
wherein the second component is connected to the first component by bonding the copper protruding portions to the copper connector, and the copper protruding portions are in contact with the copper connector.

2. The semiconductor package structure as claimed in claim 1, wherein the first component is a die, a chip or a system-on-chip (SOC).

3. The semiconductor package structure as claimed in claim 1, wherein the second component is a package substrate, a heat spreader or an interposer substrate, and the copper connector is a copper pad.

4. The semiconductor package structure as claimed in claim 3, wherein the copper protruding portions and the copper connector form a fused layer having copper nano-pillars.

5. The semiconductor package structure as claimed in claim 4, wherein the fused layer includes voids that are distributed randomly.

6. The semiconductor package structure as claimed in claim 1, wherein an average diameter of the copper protruding portions is within a range of about 20 nm to about 200 nm.

7. The semiconductor package structure as claimed in claim 1, wherein the bonding structure on the first component is referred to as a first bonding structure and comprises a first copper base and first copper protruding portions, and the copper connector on the second component is a second bonding structure, wherein the second bonding structure comprises:
a second copper base disposed on the second component; and
second copper protruding portions disposed on the second copper base.

8. The semiconductor package structure as claimed in claim 7, wherein the first copper protruding portions are staggered with respect to the second copper protruding portions and in direct contact with the second copper protruding portions when the first bonding structure is bonded to the second bonding structure.

9. The semiconductor package structure as claimed in claim 8, wherein the first copper protruding portions and the second copper protruding portions form a copper fused layer, and the copper fused layer has voids randomly distributed in the copper fused layer.

10. The semiconductor package structure as claimed in claim 7, wherein the second component is a semiconductor wafer or a package substrate.

11. The semiconductor package structure as claimed in claim 7, wherein the first component is a die, and the bonding structure is formed on a backside of the die, wherein the copper base is in direct contact with the backside of the die.

12. The semiconductor package structure as claimed in claim 11, wherein the second component is a heat spreader or an interposer substrate, and the first bonding structure on the die is bonded to the second bonding structure on the second component through direct contact between the first copper protruding portions and the second copper protruding portions.

13. A method of forming a semiconductor package structure, comprising:
providing a first component;
forming a bonding structure on the first component, the bonding structure comprising:
a copper base, disposed on the first component; and
copper protruding portions, disposed on the copper base;
providing a second component with a copper connector formed thereon; and
connecting the first component to the second component by bonding the copper protruding portions to the copper connector, wherein the copper protruding portions are in contact with the copper connector.

14. The method as claimed in claim 13, wherein the copper protruding portions on the first component are bonded to the copper connector on the second component at room temperature.

15. The method as claimed in claim 13, wherein the copper protruding portions on the first component are bonded to the copper connector at a temperature of about 25° C. to about 250° C.

16. The method as claimed in claim 13, wherein forming the bonding structure comprises:
forming a patterned photoresist layer over the first component, wherein the patterned photoresist layer has an opening that exposes a pad coupled to the first component;
plating copper in the opening to form the copper base;
forming a template on the patterned photoresist layer and the copper base, wherein the template comprises penetrating holes that expose the patterned photoresist layer and the copper base;
plating copper in the penetrating holes of the template to form the copper protruding portions on the copper base; and
removing the template and the patterned photoresist layer.

17. The method as claimed in claim 13, wherein the copper protruding portions are arranged in an array of copper nano-pillars that protrude from the copper base before the first component is bonded to the second component.

18. The method as claimed in claim 13, wherein after the bonding structure is bonded to the copper connector, the method further comprises:
performing a thermal treatment on the copper protruding portions and the copper connector.

19. The method as claimed in claim 13, wherein the copper connector is a copper pad, and the copper protruding portions and the copper pad form a copper fused layer after the bonding structure is bonded to the copper pad.

20. The method as claimed in claim 19, wherein the copper fused layer includes fused nano-copper pillars and voids that are randomly formed between the fused nano-copper pillars.

21. The method as claimed in claim 13, wherein the bonding structure on the first component is referred to as a first bonding structure and comprises a first copper base and first copper protruding portions, and a second bonding structure on the second component is referred as the copper connector, wherein the second bonding structure comprises:
a second copper base disposed on the second component; and
second copper protruding portions disposed on the second copper base.

22. The method as claimed in claim 21, wherein the first copper protruding portions are staggered with respect to the second copper protruding portions and in direct contact with the second copper protruding portions when the first bonding structure is bonded to the second bonding structure for electrically connecting the first component to the second component.

23. The method as claimed in claim 22, wherein after the first bonding structure is bonded to the second bonding structure, the first copper protruding portions and the second copper protruding portions form a copper fused layer, and the copper fused layer has voids that are randomly distributed in the copper fused layer.

24. The method as claimed in claim 13, wherein the first component is a die, the second component is a heat spreader or an interposer substrate, and the bonding structure is formed on a backside of the die, wherein the bonding structure on the die is in direct contact with the copper connector.

25. A semiconductor package assembly, comprising:
a package substrate;
an interposer stacked on the package structure;
a first bonding layer between the package structure and the interposer;
a device package stacked on the interposer; and
a second bonding layer between the device package and the interposer,
wherein the device package is electrically connected to the package substrate through the second bonding layer and the first bonding layer, and
wherein at least one of the first bonding layer and the second bonding layer includes a bonding set, and the bonding set comprises copper protruding portions between a copper base and a copper connector, and the copper protruding portions are in direct contact with the copper base and the copper connector.

26. The semiconductor package assembly as claimed in claim 25, wherein the copper protruding portions are referred to as first copper protruding portions, and the copper connector comprises second copper protruding portions, wherein the first copper protruding portions are staggered with respect to the second copper protruding portions and in direct contact with the second copper protruding portions to form a copper fused layer.

27. The semiconductor package assembly as claimed in claim 25, wherein the first bonding layer includes the bonding set, and the copper base and a copper connector are respectively on the package structure and the interposer, and
wherein the copper protruding portions and the copper connector form a copper fused layer that includes fused nano-copper pillars.

28. The semiconductor package assembly as claimed in claim 25, wherein the second bonding layer includes the bonding set, and the copper base and a copper connector are respectively on the device package and the interposer, and
wherein the copper protruding portions and the copper connector form a copper fused layer that includes fused nano-copper pillars.

29. The semiconductor package assembly as claimed in claim 25, further comprising:
a printed circuit board (PCB) coupled to the package substrate by a third bonding layer,
wherein the third bonding layer includes another bonding set having an identical configuration as the bonding set of the first bonding layer or the second bonding layer.
